(19) United States
(12) Patent Application Publication
(10) Pub. No.: US 2024/0283401 A1
(43) Pub. Date: Aug. 22, 2024

(54) COOLING SYSTEM FOR A PHOTOVOLTAIC SOLAR PANEL

(71) Applicant: SOLTEC INNOVATIONS, S.L., Molina de Segura (ES)

(72) Inventor: Francisco Javier TORRANO CARRILLO, Molina de Segura (ES)

(73) Assignee: SOLTEC INNOVATIONS, S.L., Molina de Segura (ES)

(21) Appl. No.: 18/571,241

(22) PCT Filed: Jun. 15, 2022
(86) PCT No.: PCT/EP2022/066357

§ 371 Date: Dec. 17, 2023

(30) Foreign Application Priority Data
Jun. 18, 2021 (EP) 21382540.9

(51) Int. Cl. H02S 40/34; H02S 40/42

(52) U.S. Cl. CPC H02S 40/345; H02S 40/425

(57) ABSTRACT

A solar panel includes photovoltaic cells; fingers; and busbars, heat exchangers in contact with the busbar (s) for receiving heat from the busbar by conductivity; and refrigeration means or retiring heat from the heat exchanger(s) to an ambient. Heat exchangers may be selected among: electrically insulant heat exchangers provided in several discrete locations of the busbar(s); or exchanging duct(s) located along the busbar(s) or portions thereof, within which a cooling fluid flows. Refrigeration may be selected from Peltier thermoelectrical refrigerating elements; and a refrigerating machine including: evaporator; compressor; condenser; refrigerating ducts through which a cooling fluid flows; and an expansion valve located on the refrigerating ducts. It limits shadowing provided by cooling systems in the previous art.

### CROSS-REFERENCE TO RELATED APPLICATIONS

This application is a national stage under 35 U.S.C. § 371 of PCT patent application PCT/EP2022/066357 filed on 15 Jun. 2022, which is pending and which is hereby incorporated by reference in its entirety for all purposes.

PCT/EP2022/066357 claims priority to European Patent Application 21382540.9 filed 18 Jun. 2021, which is hereby incorporated by reference in its entirety for all purposes.

### TECHNICAL FIELD OF THE INVENTION

The present invention may be included within the technical field of solar energy. In particular, the object of the invention relates to a cooling system for cooling photovoltaic solar panel(s).

### BACKGROUND OF THE INVENTION

A photovoltaic solar panel comprises photovoltaic cells, for transforming sun radiation into electrical energy. The energy from the cells is gathered by conductors referred to as “fingers”, usually made of copper, which transport the energy to busbars, also usually made of copper, which interconnect the cells in series and in parallel, so as to form one or several strings in a solar module.

The efficiency of a photovoltaic solar panel is strongly affected by the temperature of the photovoltaic cell during operation, wherein each 1° C. of deviation with respect to NOTC (Nominal Operating Cell Temperature) causes a loss of power extracted from the cell of 0.3-0.35%. Since NOTC is usually about 45° C. and the operating temperature often reaches around 65° C. under a 1000 W/m² radiation and an ambient temperature of 35° C. (which is often the case in desertic or arid locations where great photovoltaic installations take place), the loss of power is significant due to an excess temperature of the photovoltaic cell.

Documents, such as CN207265978, are known, describing solutions for photovoltaic module cooling systems, wherein one or several heat exchangers are mounted on a rear part of the module for cooling the module. These solutions have the drawbacks that the cooling system shares a valuable space with the solar panels, so that shadowing of the panels is produced.

### SUMMARY OF THE INVENTION

The present invention provides a cooling system for cooling the busbar(s) of a photovoltaic solar panel.

The cooling system comprises heat exchangers in contact to the busbars, because, due to the thermal conductivity of the busbars, cooling the busbars results in cooling the whole solar panel.

The cooling system of the invention limits the shadows provided by refrigeration equipment, and is applicable to both monofacial and bifacial photovoltaic panels.

### BRIEF DESCRIPTION OF THE DRAWINGS

All preceding, as well as other, features and advantages, shall be better understood in the light of the following detailed description of preferred embodiments of the invention, with reference to the attached drawings, which are to be considered for illustrative, non-limiting purposes, and wherein:

FIG. 1 shows a perspective view of an arrangement of the heat exchangers according to a first preferred embodiment.

FIG. 2 shows a schematic perspective view of an arrangement of a refrigeration means according to a first example of the first preferred embodiment.

FIG. 3 shows a schematic perspective view of an arrangement of a refrigeration means according to a second example of the first preferred embodiment.

FIG. 4 shows a perspective view of an arrangement of the heat exchangers according to a second preferred embodiment.

FIG. 5 shows a flow chart of a first example of refrigeration means for the second preferred embodiment.

FIG. 6 shows a flow chart of a second example of refrigeration means for the first and the second preferred embodiments.

### DETAILED DESCRIPTION OF A PREFERRED EMBODIMENT OF THE INVENTION

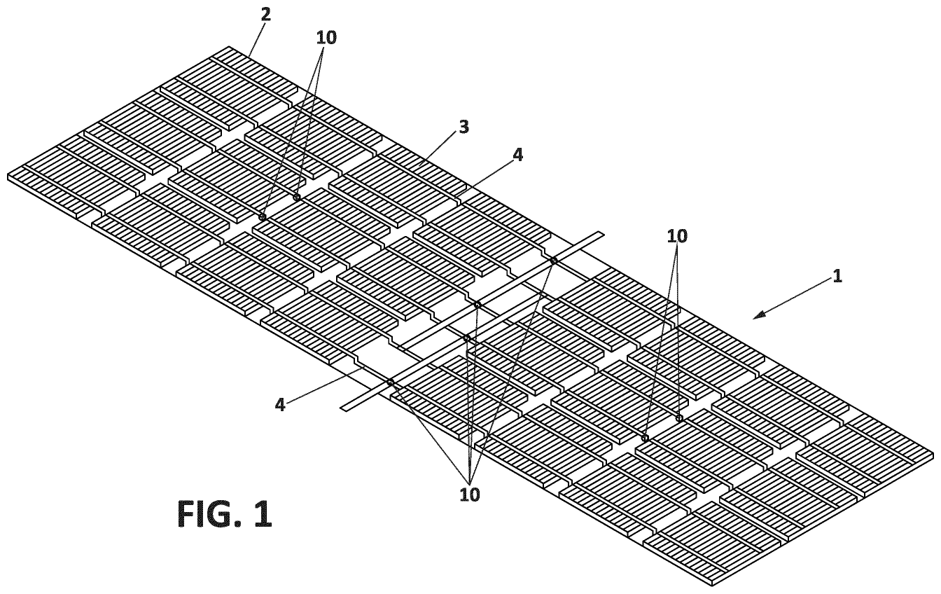

Next, a detailed description of preferred embodiments of the invention is provided with the help of above-mentioned FIGS. 1-6.

The cooling system of the invention is intended to be applied to a solar installation comprising one or several photovoltaic solar panels (1), the panels (1) comprising: photovoltaic cells (2); fingers (3) for gathering electricity from the cells (2); and one or several busbars (4) for grouping the electricity gathered by the fingers (3) and interconnecting the cells (2).

The cooling system comprises at least one heat exchanger (5, 6) in contact with the at least one busbar (4) of one or several of the solar panels (1). Due to the high heat conductivity of the busbar(s) (4), heat is easily transferred from the busbar(s) (4) to the heat exchanger(s) (5, 6). The cooling system further comprises refrigeration means (7, 8, 9) for retiring the heat from the heat exchangers (5, 6) to an ambient.

Next, two preferred embodiments of the heat exchangers (5, 6) are described. For each preferred embodiment, two preferred examples of refrigeration means (7, 8, 9) are described.

### Embodiment 1: Discrete Cooling

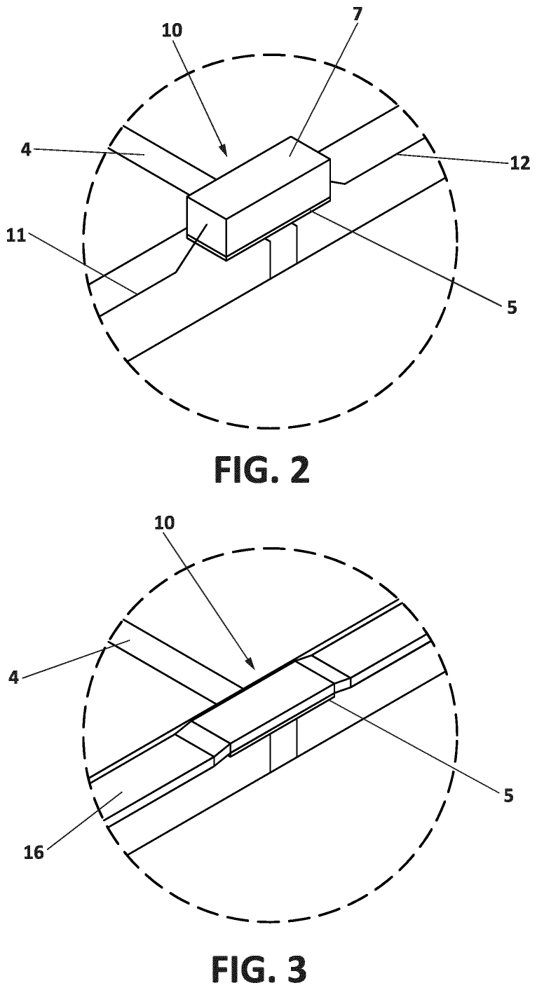

In this first preferred embodiment, according to FIG. 2, a number of electrically insulant heat exchangers (5) are provided in several discrete locations (10) i.e., points of the busbar(s) (4). The electrically insulant heat exchangers (5) may be any kind of conventional, commercially available heat exchangers (5), such as, for instance, thermal pads.

The refrigeration means (7, 8, 9) for the first embodiment may comprise, as a first example thereof, see FIG. 2, one or several thermoelectrical refrigerating elements (7), in contact to the electrically insulant heat exchangers (5), operating according to the Peltier effect, and electrically powered through a positive conductor (11) and a negative conductor (12) of a power source (not shown). The power source may be fed by a part of the energy provided by the panel (1) itself, by including corresponding current-conditioning elements, such as commercially available DC/DC converters.

A second example of refrigeration means (7, 8, 9) for the first embodiment relates, see FIGS. 3 and 6, to a refrigerating machine (8) operating through a Reverse Carnot Cycle or, more accurately, through a simple mechanical vapor-compression refrigerating machine, wherein the refrigerating machine (8) comprises:
an evaporator (13), including all the heat exchangers (5, 6);
a compressor (14);
a condenser (15);
refrigerating ducts (16) through which a cooling fluid flows; and
an expansion valve (17) located on the refrigerating ducts (16).

### Embodiment 2: Continuous Cooling

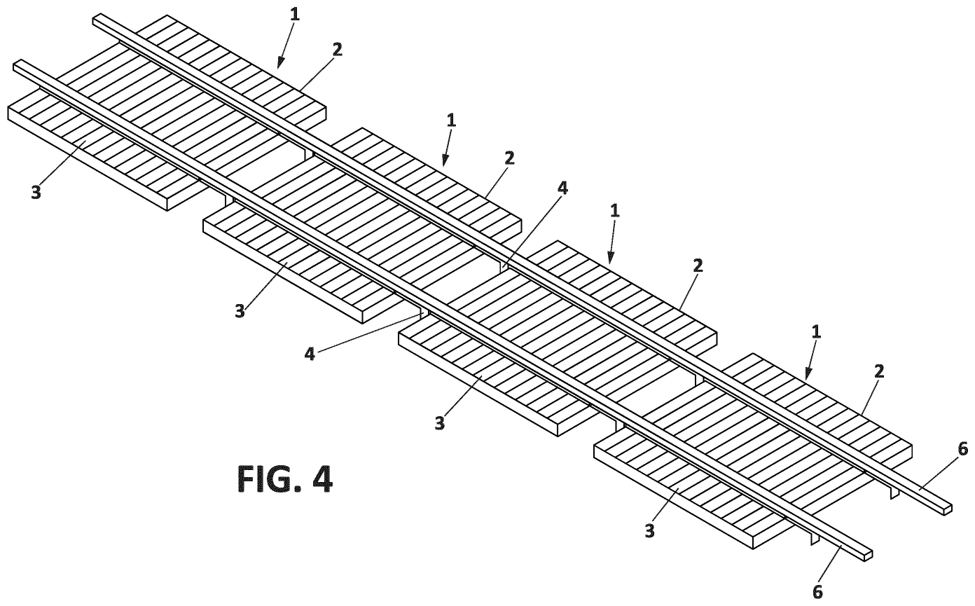

In this second preferred embodiment, according to FIG. 4, the heat exchangers (5, 6) comprise one or several exchanging ducts (6) located along, and in contact to, the busbar(s) (4) or portions thereof. Preferably the exchanging ducts (6) have a width equal to that of the busbar(s) (4). A cooling fluid flows within the exchanging ducts (6).

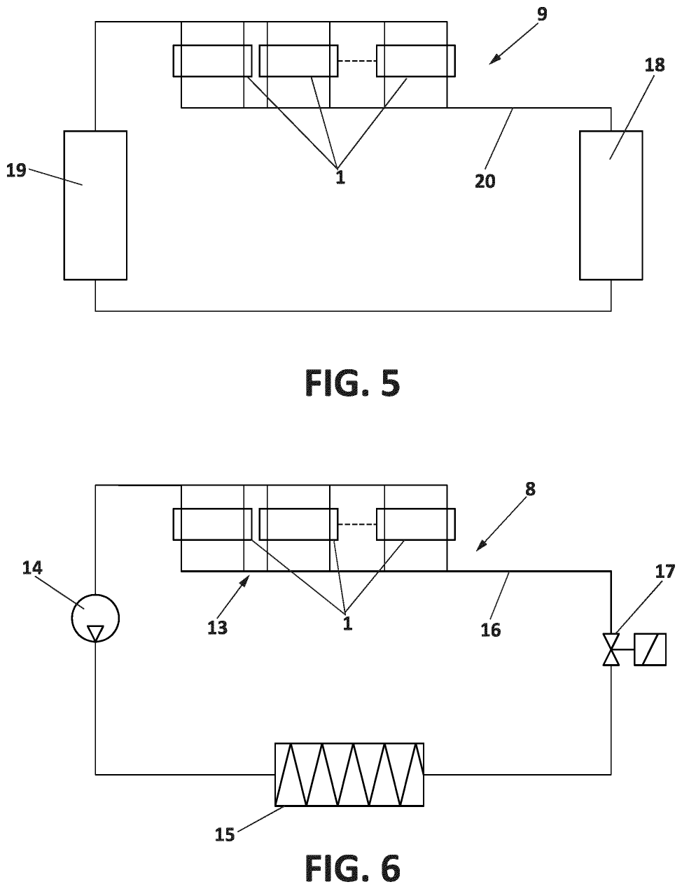

The refrigeration means (7, 8, 9) for the second embodiment may comprise, as a first example thereof, see FIG. 5, natural-convection refrigeration means (9). In this case, the natural-convection refrigerating means (9) comprises a dissipation, colder deposit (18) for the cooling fluid (20) and a hotter deposit (19) for the cooling fluid (20), wherein the cooling fluid (20) flows from the hotter deposit (19) to the colder deposit (18) due to natural convection produced by temperature difference of the deposits (18, 19).

The cooling fluid comprises sulfur hexafluoride SF6.

According to a second example, see FIGS. 5 and 6, the refrigeration means (7, 8, 9) of the second embodiment, may be the refrigerating machine (8) as explained above for the second example of the first embodiment, wherein, in both cases, an impulse system (not shown) for impulsing the cooling fluid is connected in parallel to the refrigerating ducts (16), so that the cooling fluid enters at one same initial temperature in all the refrigerating ducts (16). One same impulse system may feed cooling fluid for one or several photovoltaic panels (1). The panel (1) itself may fed the impulse system, through a corresponding current conditioning, as explained above for the power source.

1.-11. (canceled)

12. A cooling system for cooling a photovoltaic solar panel, the cooling system comprising:
the photovoltaic solar panel comprising photovoltaic cells, fingers for gathering electrical energy from the photovoltaic cells, at least one busbar for grouping the electricity gathered by the fingers and interconnecting the photovoltaic cells;
at least one heat exchanger or receiving heat from the at least one busbar by conductivity; and
a refrigeration means for retiring the heat from the heat exchange to an ambient environment;
wherein at least one heat exchanger is in contact with the at least one busbar of the solar panel.

13. The cooling system according to claim 12, wherein the heat exchangers comprise a plurality of electrically insulated heat exchangers provided in several discrete locations of the at least one busbar.

14. The cooling system according to claim 13,
wherein the refrigeration means comprises at least one thermoelectrical refrigerating element,
the at least one thermoelectrical refrigerating element in contact with the electrically insulated heat exchangers, operating according to the Peltier effect, and electrically powered through a positive conductor and a negative conductor of a power source.

15. The cooling system according to claim 11,
wherein the heat exchangers comprise:
at least one exchanging duct located along and in contact with the at least one busbar or portions thereof; and
a cooling fluid flowing within the at least one exchanging duct.

16. The cooling system according to claim 15, wherein the at least one exchanging duct has a width equal to that of the at least one busbar.

17. The cooling system according to claim 13,
wherein the refrigeration means comprises a natural-convection refrigeration means comprising:
a dissipation, colder deposit for cooling fluid; and
a hotter deposit for the cooling fluid,
wherein the cooling fluid flows from the hotter deposit to the colder deposit due to natural convection produced by temperature difference of the colder deposit and hotter deposit.

18. The cooling system according to claim 13,
wherein the refrigeration means comprises a refrigerating machine, the refrigeration machine comprising:
an evaporator, including all the heat exchangers;
a compressor;
a condenser;
refrigerating ducts through which a cooling fluid flows; and
an expansion valve.

19. The cooling system according to claim 18, wherein an impulse system for impulsing the cooling fluid is connected in parallel to the refrigerating ducts, so that the cooling fluid enters at one same initial temperature in all the refrigerating ducts.

20. The cooling system according to claim 15, wherein the cooling fluid comprises sulfur hexafluoride SF6.

21. A photovoltaic solar installation comprising:
at least one photovoltaic solar panel;
a cooling system for cooling the at least one photovoltaic solar panel, the cooling system comprising:
the at least one photovoltaic solar panel comprising photovoltaic cells, fingers for gathering electrical energy from the photovoltaic cells, at least one busbar for grouping the electricity gathered by the fingers and interconnecting the photovoltaic cells;
at least one heat exchanger or receiving heat from the at least one busbar by conductivity; and
a refrigeration means for retiring the heat from the heat exchange to an ambient environment;
wherein the at least one heat exchanger is in contact with the at least one busbar of the solar panel.

22. The photovoltaic solar installation according to claim 21,
wherein the at least one photovoltaic solar panel are more than two photovoltaic solar panel; and
the photovoltaic solar installation according further comprising
an impulse system for impulsing the cooling fluid, the impulse system being connected in parallel to the refrigerating ducts, so that the cooling fluid enters at one same initial temperature in all the refrigerating ducts, wherein the impulse system feeds cooling fluid for more than one of the photovoltaic solar panels.
